(19) United States
(12) Patent Application Publication
(10) Pub. No.: US 2010/0087033 A1
(43) Pub. Date: Apr. 8, 2010

(54) METHOD AND APPARATUS FOR MANUFACTURING SEMICONDUCTOR DEVICE

(75) Inventors: Keita Mizoguchi, Kanagawa-ken (JP); Soichi Homma, Kanagawa-ken (JP)

Correspondence Address: TUROCY & WATSON, LLP, 127 Public Square, 57th Floor, Key Tower, CLEVELAND, OH, 44114, US

(73) Assignee: KABUSHIKI KAISHA TOSHIBA, Tokyo (JP)

(21) Appl. No.: 12/570,590

(22) Filed: Sep. 30, 2009

(30) Foreign Application Priority Data
Oct. 3, 2008 (JP) 2008-258825

(51) Int. Cl. H01L 21/50; H01L 21/67

(52) U.S. Cl. 438/107; 29/25.01; 257/E21.499

(57) ABSTRACT

A resin layer is formed on a support substrate. An intermediate structure body is formed on the resin layer. The support substrate is fixed to a first unit configured to fix and heat. The intermediate structure body is fixed to a second unit configured to fix and heat. The support substrate and the intermediate structure body are heated by the first unit or the second unit, so as to soften the resin layer. The second unit is moved with respect to the first unit along each of a plurality of line segments or a curve, so as to enlarge a distance between a center of the support substrate and a center of the intermediate structure body as the second unit moves, while the support substrate and the intermediate structure body being kept in the horizontal state, and until the support substrate and the intermediate structure body are separated.

### CROSS REFERENCE TO RELATED APPLICATION

This application is based upon and claims the benefit of priority from the prior Japanese Patent Application No. 2008-258825, filed on Oct. 3, 2008, the entire contents of which are incorporated herein by reference.

### FIELD OF THE INVENTION

The invention relates to a method and an apparatus for manufacturing a semiconductor device.

### DESCRIPTION OF THE BACKGROUND

In a dual-sided semiconductor device, a resin substrate or a silicon substrate is frequently used as a substrate on which multiple semiconductor chips are stacked, whereas an insulative resin or the like is used as a printed circuit board that includes wiring.

A dual-sided semiconductor device is fabricated, for example, in a method including: preparing a predetermined support substrate; forming a printed circuit board on the support substrate by placing a resin, which is a material for the printed circuit board, on the support substrate, and then by forming a wiring layer in the resin thus placed; mounting a semiconductor chip on a first surface of the printed circuit board; then removing the support substrate from the printed circuit board; and thereafter additionally forming another semiconductor chip on a second surface of the printed circuit board with another wiring layer formed in between. The total thickness of the printed circuit board, the semiconductor chips, and the like is as thin as approximately 100 μm in many cases, so that the removal of the support substrate is frequently difficult.

As a technique in a technical field similar to that of the invention, the JP-A 2007-287911 discloses a technique of separating a semiconductor wafer bonded on a support substrate with an adhesive agent. More specifically, this patent document discloses a method for a work in which a semiconductor wafer is bonded to a support substrate with an adhesive agent. In this method, the work is clamped between an upper-side holding mechanism unit and a lower-side holding mechanism unit with a porous sheet placed on a drawing surface of the lower-side holding mechanism unit and with the back side of the work placed on the porous sheet. Here, on the back side of the work, the wafer bonded to the support substrate with the adhesive agent is exposed, and the entire back-side surface of the wafer is drawn and thus held by a uniform sucking force of the lower-side holding mechanism unit. Then, heaters built in the upper-side and lower side holding mechanism units heats and melts the adhesive agent. While drawing the support substrate, the upper-side holding mechanism unit is moved horizontally and linearly. Thereby, the wafer held by the lower-side holding mechanism unit with the porous sheet interposed in between is separated from the support substrate.

If used in a process of manufacturing a dual-sided semiconductor apparatus to separate a supporting substrate from a printed circuit board, however, this separation method brings about a problem of sometimes causing cracks in the printed circuit board or breaking the wiring of the printed circuit board, thereby causing a decrease in fabrication yield of the semiconductor device.

### SUMMARY OF THE INVENTION

One aspect of the invention is to provide a method of manufacturing a semiconductor device including, forming a resin layer on a wafer-like support substrate, the resin being a thermoplastic resin, forming a wafer-like intermediate structure body on the resin layer, the intermediate structure body including a printed circuit board, a semiconductor chip mounted on the printed circuit board and a molding resin to cover an upper surface of the printed circuit board and the semiconductor chip, fixing the support substrate to a first unit, the first unit being configured to fix and heat the support substrate, fixing the intermediate structure body to a second unit arranged opposite to the first unit, the second unit being configured to fix and heat the intermediate structure body, heating the support substrate and the intermediate structure body by the first unit or the second unit, so as to soften the resin layer, and moving the second unit with respect to the first unit along each of a plurality of line segments or a curve, so as to enlarge a distance between a center of the support substrate and a center of the intermediate structure body as the second unit moves, while the support substrate and the intermediate structure body being kept in the horizontal state, and until the support substrate and the intermediate structure body are separated.

Another aspect of the invention is to provide a method of manufacturing a semiconductor device including, forming a metal layer on a wafer-like support substrate, forming a wafer-like intermediate structure body on the metal layer, the intermediate structure body including a printed circuit board, a semiconductor chip mounted on the printed circuit board and a molding resin to cover a upper surface of the printed circuit board and the semiconductor chip, fixing the support substrate to a first unit, the first unit being configured to fix and heat the support substrate, fixing the intermediate structure body to a second unit arranged opposite to the first unit, the second unit being configured to fix and heat the intermediate structure body, heating the support substrate and the intermediate structure body by the first unit or the second unit, supplying a ultrasonic power to the metal layer through the support substrate or the intermediate structure body, moving the second unit with respect to the first unit in a horizontal direction and at a constant speed with vibration, while the support substrate and the intermediate structure body being kept in the horizontal state, and moving the second unit with respect to the first unit in a vertical direction and at a constant speed with vibration, wherein the horizontal movement and the vertical movement are repeated until the support substrate and the intermediate structure body are separated.

Another aspect of the invention is to provide an apparatus for manufacturing a semiconductor device including, a first unit to fix and heat including a first heating portion and a second heating portion respectively to heat a center portion of a work and a peripheral portion of the work independently, the first heating portion and the second heating portion having a vacuum chuck on the side of the work, a second unit to fix and heat including a third heating portion and a forth heating portion respectively to heat the center portion of the work and the peripheral portion of the work independently, the third heating portion and the forth heating portion having a vacuum chuck on the side of the work, the second unit being arranged oppositely to the first unit, and a movement mechanism unit configured to move the second unit with respect to the first unit in a plurality of mutually different directions on a plane when the work is heated.

### BRIEF DESCRIPTION OF THE DRAWINGS

FIG. 1 is a flowchart illustrating in the order of steps a method of manufacturing a semiconductor device according to a first embodiment of the invention.

FIGS. 2A to 2E are structural sectional views illustrating in the order of steps the method of manufacturing the semiconductor device according to the first embodiment of the invention.

FIG. 3 is a top plan view illustrating a portion at a manufacturing step of the semiconductor device according to the first embodiment of the invention.

FIGS. 4A and 4B are diagrams each illustrating portions of the semiconductor device and a manufacturing apparatus at a step of manufacturing the semiconductor apparatus according to the first embodiment of the invention. FIG. 4A is a sectional view before the movement is started whereas FIG. 4B is a sectional view at the time the movement is finished.

FIGS. 5A and 5B are diagrams each illustrating a portion of the apparatus for manufacturing the semiconductor device according to the first embodiment of the invention. FIG. 5A is a sectional view whereas FIG. 5B is a partially-cutaway top plan view.

FIG. 6 is a plan view illustrating a separation movement from a state shown in FIG. 4A to a state shown in FIG. 4B at a step of manufacturing the semiconductor device according to the first embodiment of the invention.

FIG. 7 is a plan view illustrating a separation movement at a step of manufacturing a semiconductor device according to a second embodiment of the invention.

FIG. 8 is a sectional view illustrating a portion of an apparatus for manufacturing a semiconductor device according to a third embodiment of the invention.

FIGS. 9A and 9B are plan view illustrating a separation movement at a step of manufacturing the semiconductor device according to the third embodiment of the invention.

FIG. 10 is a plan view illustrating a separation movement at a step of manufacturing a semiconductor device according to a modification of the third embodiment of the invention.

FIGS. 11A and 11B are diagrams each illustrating a portion of an apparatus for manufacturing a semiconductor device according to a fourth embodiment of the invention. FIG. 11A is a sectional view whereas FIG. 11B is a chart illustrating the temperature distribution of a strip layer.

### DETAILED DESCRIPTION OF THE INVENTION

Embodiments of the invention will be described with reference to the drawings. If a member appears in different drawings, the member is denoted by the same reference numeral.

### First Embodiment

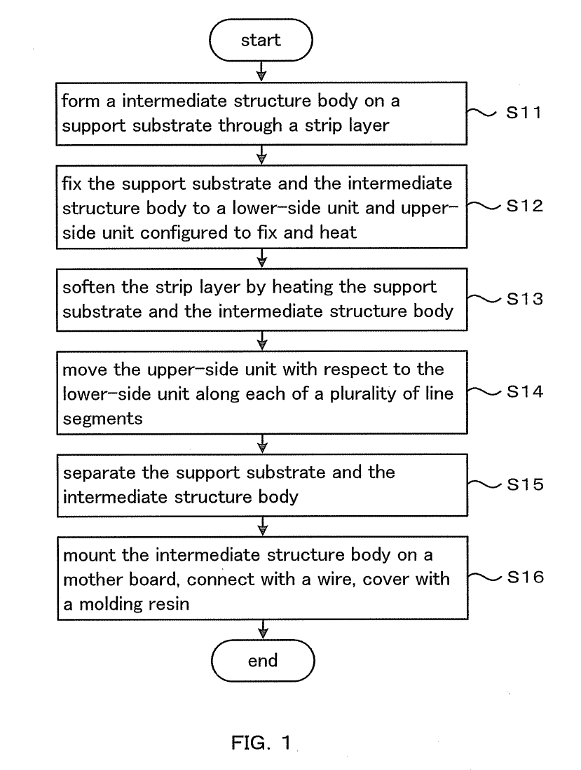

A method and an apparatus for manufacturing a semiconductor device according to a first embodiment will be described with reference to FIGS. 1 to 6.

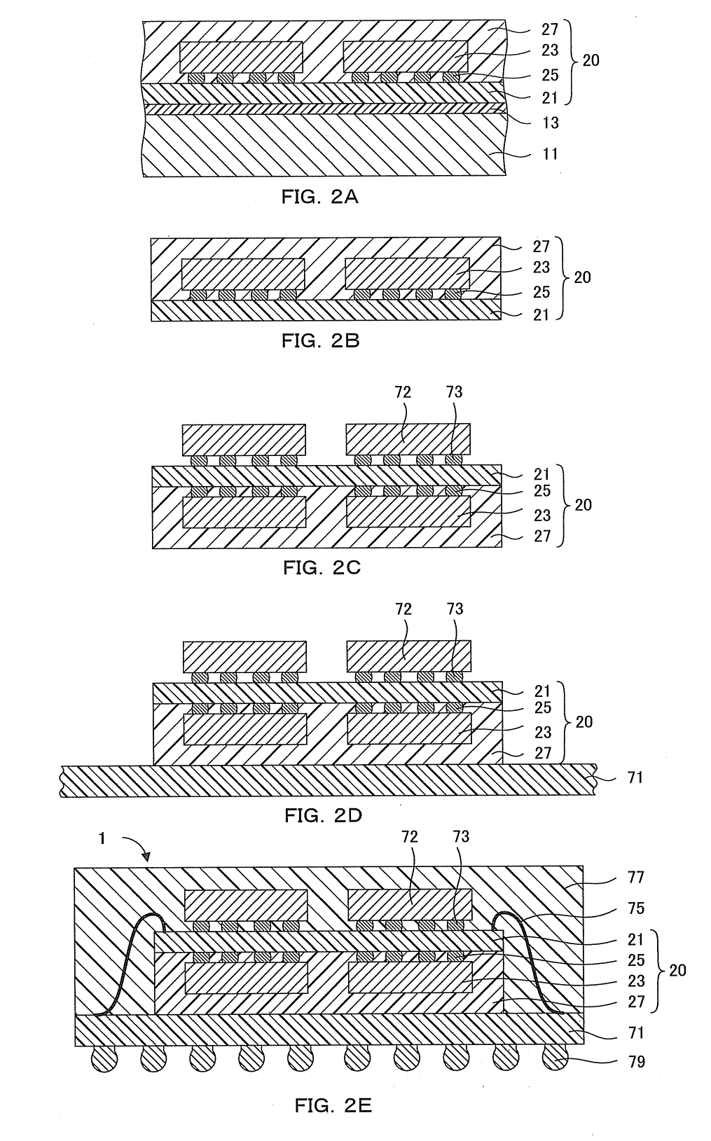

As FIG. 1 shows, the semiconductor-device manufacturing method includes manufacturing processes from step S11 to step S16. A semiconductor device 1 shown in FIG. 2E is completed through these processes.

As FIG. 2E shows, the semiconductor device 1 includes a mother board 71. A printed circuit board 21 is fixed to a first surface of the mother board. Semiconductor chips 23, 72 are connected to the two surfaces of the printed circuit board 21 with solder bumps 25, 73 placed in between. In addition, solder bumps 79 are placed on a second surface of the mother board 71. Though not illustrated, wirings are formed on the two surfaces of the printed circuit board 21. Pads that are connected to the semiconductor chips 23, 72 are formed in some portions of the wirings. Some of the wirings penetrate the printed circuit board 21. Wirings are formed on the two surfaces of the mother board 71. Pads that are connected to the printed circuit board 21 are formed in some portions of the wirings. Some of the wirings penetrate the mother board 71 and are connected to the solder bumps 79. Metal fine wires 75 are provided to connect the mother board 71 and the printed circuit board 21. A molding resin 27 is provided on the printed circuit board 21 so as to cover the semiconductor chips 23. The opposite surface of the molding resin 27 to the printed circuit board 21 is fixed to the mother board 71. A surface of the mother board facing the printed circuit board 21 is covered by a molding resin 77, which also covers the semiconductor chips 72, the printed circuit board 21, the metal fine wires 75, the molding resin 27, and the like. Note that neither solder resists nor underfills are illustrated in FIGS. 2A to 2E.

As FIGS. 1 and 2A show, the semiconductor-device manufacturing method starts with forming a wafer-like support substrate 11, then forming a strip layer 13, which is a thermoplastic resin layer, on top of the support substrate 11, and then forming a wafer-like intermediate structure body 20 on top of the strip layer 13 (step S11). The intermediate structure body 20 includes: the printed circuit board 21 on which the wirings are formed and which is formed on top of the strip layer 13; the semiconductor chips 23 that are fixed on and are electrically connected to the printed circuit board 21; and the molding resin 27 that covers the upper surface of the printed circuit board 21 and the semiconductor chips 23.

The strip layer 13 is made of polystyrene, for example. The viscosity of the strip layer 13 is lowered at a temperature of 200 to 250° C. The strip layer 13 serves as an interface to separate the support substrate 11 and the intermediate structure body 20 from each other at a later process. Accordingly, it is preferable that the strip layer 13 should have a viscosity of 1×10⁵ cps or lower at 250° C. Besides polystyrene, methacrylate resin, polyethylene, polypropylene, or the like can be used to form the strip layer 13. The thickness of the strip layer 13 is in the order of several micrometers to several tens of micrometers.

Though not illustrated, the printed circuit board 21 is formed in the following way. Specifically, a conductive film which will be the wirings and which is made of a metal or the like is formed on top of the strip layer 13. Then, the conductive film is subjected to a patterning process so that the wirings and the pads can be left on the strip layer 13. Then, an insulating film that is made of a thermosetting resin, for example, is formed on the wirings and pads thus left. Then, vias are formed so as to penetrate the insulating film, and the vias are filled with conductive bodies made of a similar material to that of the conductive film. A conductive film is formed on top of the insulating film so as to be connected to the vias. Then, the conductive film is subjected to a patterning process so that the wirings and the pads can be left on the insulating film. Note that it is possible to form the vias to be so large that the vias can serve also as the pads and thereby to eliminate the first patterning process of the conductive film. In addition, the printed circuit board 21 may include plural insulating films and plural conductive films required for the plural insulating films. Pads that can be connected to the semiconductor chips 23, 72 are formed on the two surfaces of the printed circuit board 21. Pads that can be connected to the mother board 71 are formed in the peripheral portions of the printed circuit board 21 on a side facing the semiconductor chips 23.

The semiconductor chips 23 are fixed so as to be connected to the strip layer 13 through the wirings formed on the opposite surface of the printed circuit board 21 to the strip layer 13. The solder bumps 25 made of SnAg or the like are provided to connect the semiconductor chips 23 to the wirings. The molding resin 27 made of a thermosetting epoxy resin, for example, is formed on the printed circuit board 21 on a side facing the semiconductor chips 23. The molding resin 27 covers the semiconductor chips 23, and the surface of the molding resin 27 is substantially flat. The intermediate structure body 20 refers to the portion which will be separated from the strip layer 13 at a later process and which includes the printed circuit board 21, the semiconductor chips 23 and the molding resin 27.

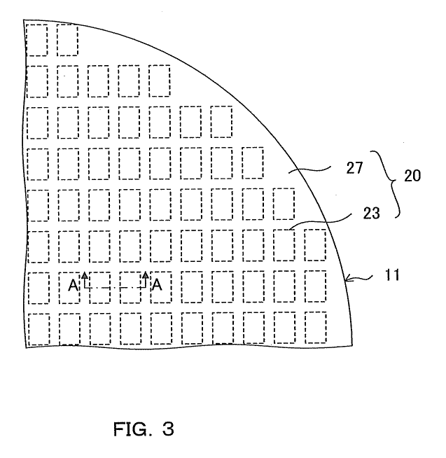

As FIG. 3 shows, each of the support substrate 11 and the intermediate structure body 20 has an approximate disc shape, which is determined by the shape of the support substrate 11 made of a silicon wafer, for example. The molding resin 27 that covers the semiconductor chips 23 and the like is exposed to the surface of the intermediate structure body 20. The sectional view of FIG. 2A corresponds substantially to the section taken along the line A-A in FIG. 3.

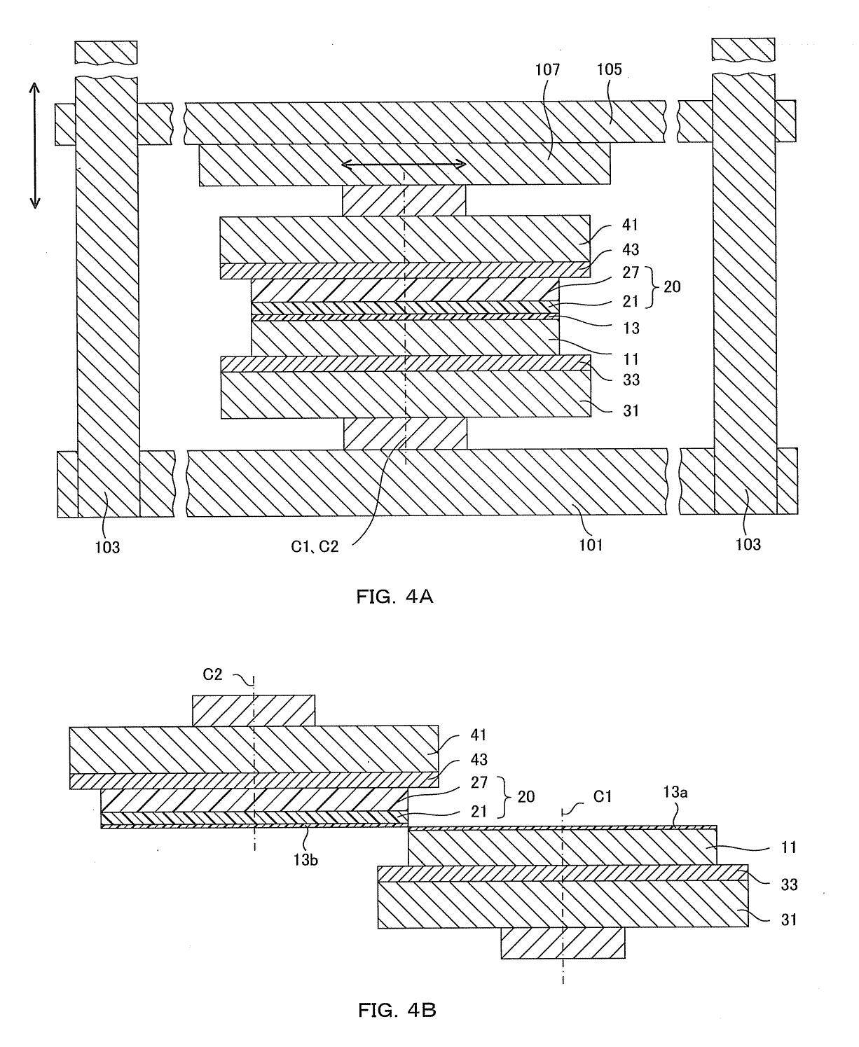

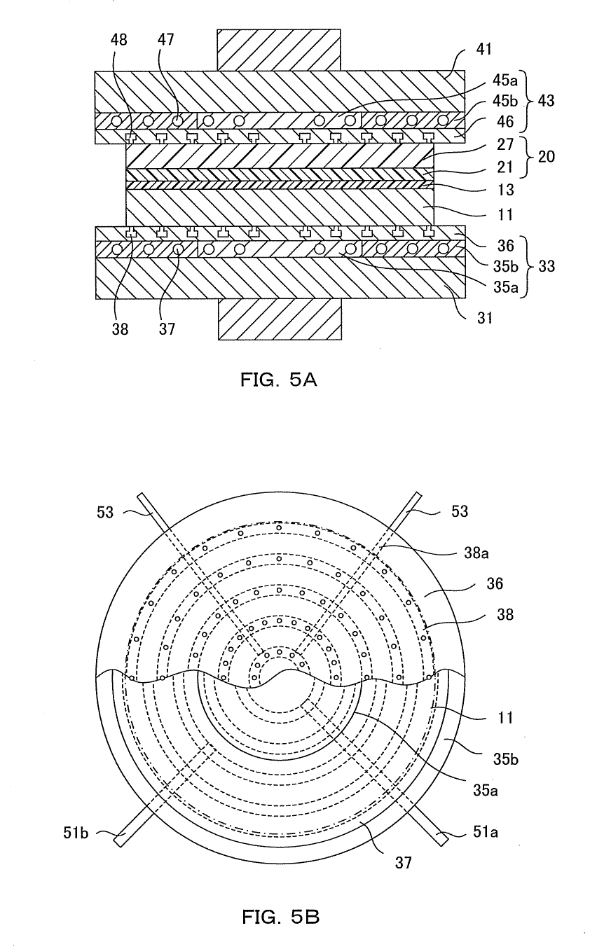

Subsequently, the separation of the intermediate structure body 20 from the support substrate 11 will be described. The separation is accomplished through steps S12 to S15 illustrated in FIG. 1, and the manufacturing apparatus illustrated in FIGS. 4 and 5 are used for this purpose.

FIG. 4A illustrates a movement mechanism unit of the manufacturing apparatus. The frames of the movement mechanism unit includes a bottom plate 101, support columns 103 that are fixed to the bottom plate 101 so as to be perpendicular to the bottom plate 101, and a top plate 105 which is capable of moving up and down along the support columns 103 (in FIG. 4A, the upward and downward movements are indicated by the double-direction arrowed line with two arrowheads directed upwards and downwards respectively) and which is capable of being fixed. A movable plate 107 is fitted to the top plate 105. The movable plate 107 is capable of moving along the bottom surface of the top plate 105, that is, capable of moving within a plane while keeping a constant distance from the bottom plate 101 (in FIG. 4A, the in-plane movements are indicated by the double-direction arrowed line with two arrowheads directed rightwards and leftwards). A lower-side table 31 is fixed to the top surface of the bottom plate 101 whereas an upper-side table 41 is fixed to the bottom surface of the movable plate 107. A lower-side unit configured to fix and heat (first unit configured to fix and heat) 33 and an upper-side unit configured to fix and heat (second unit configured to fix and heat) 43 are fixed respectively to the lower-side table 31 and to the upper-side table 41 so that these two units 33 and 43 may be opposed to each other.

As FIGS. 5A and 5B shows, the lower-side unit configured to fix and heat 33 is fixed, substantially in a horizontal manner, to the top surface of the lower-side table 31, and includes a central heating portion 35a and a peripheral heating portion 35b being a first and a second heating portions that are capable of heating respectively the central portion and the peripheral portion of the wafer-like support substrate and the intermediate structure body 20 which have been formed into a single integrated body. Heaters 37 are buried in the central heating portion 35a and the peripheral heating portion 35b in a concentric manner. Electric power is supplied to the heaters 37 from the outer-circumferential side of the lower-side unit configured to fix and heat 33 via electric-power supplying portions 51a, 51b. Although divided into two sections (center and periphery) in FIGS. 5A and 5B, the lower-side unit configured to fix and heat 33 may be divided into three or more sections.

The lower-side unit configured to fix and heat 33 includes a drawing and fixing unit 36 provided on the central heating portion 35a and the peripheral heating portion 35b on a side facing the support substrate 11. Vacuuming holes 38 are formed in the drawing and fixing unit 36 in a concentric manner. Vacuuming holes 38a that extend from the outer circumference of the drawing and fixing unit 36 towards the center of the drawing and fixing unit 36 intersect with the vacuuming holes 38. The vacuuming holes 38a directed towards the center are depressurized from the outer sides through evacuation connecting portions 53. Each of the vacuuming holes 38 has an opening in the drawing and fixing unit 36 on a side brought into contact with the support substrate 11. It is possible to hollow out the central portion of the lower-side table 31 and to draw the electric-power supplying portions 51a, 51b and the evacuation connecting portions 53 to the lower side through the hollowed-out central portion of the lower-side table 31. In addition, the surface of the drawing and fixing unit 36 can be covered with a heat-resistant resin such as a fluorine resin.

The upper-side unit configured to fix and heat 43 is fixed to the bottom surface of the upper-side table 41, and includes a central heating portion 45a and a peripheral heating portion 45b being a third and a fourth heating portions that are capable of heating respectively the central portion and the peripheral portion of the wafer-like support substrate 11 and the intermediate structure body 20 that have been formed into a single integrated body. Unillustrated heaters are buried in the central heating portion 45a and the peripheral heating portion 45b in a concentric manner. Electric power is supplied to the heaters from the outer-circumferential side of the upper-side unit configured to fix and heat 43 via electric-power supplying portions. Although divided into two sections (center and periphery) in FIGS. 5A and 5B, the upper-side unit configured to fix and heat 43 may be divided into three or more sections.

The upper-side unit configured to fix and heat 43 includes a drawing and fixing unit 46 provided on the central heating portion 45a and the peripheral heating portion 45b on a side facing the intermediate structure body 20. Though not illustrated, vacuuming holes are formed in the drawing and fixing unit 46 in a concentric manner, and other vacuuming holes that extend from the outer circumference of the drawing and fixing unit 46 towards the center of the drawing and fixing unit 46 intersect with the concentrically-formed vacuuming holes. The vacuuming holes directed towards the center are depressurized from the outer sides through evacuation connecting portions. Each of the concentrically-formed vacuuming holes has an opening in the drawing and fixing unit 46 on a side brought into contact with the intermediate structure body 20. It is possible to hollow out the central portion of the upper-side table 41 and to draw the electric-power supplying portions and the evacuation connecting portions to the top side through the hollowed-out central portion of the upper-side table 41. In addition, the surface of the drawing and fixing unit 46 can be covered with a heat-resistant resin such as a fluorine resin.

As FIGS. 1 and 4A show, the opposite surface of the support substrate 11 to the strip layer 13 is fixed to the lower-side unit configured to fix and heat 33 whereas the opposite surface of the intermediate structure body 20 to the strip layer 13 is fixed to the upper-side unit configured to fix and heat 43 (step S12). Since the intermediate structure body 20 is formed above the support substrate 11, a line (center line) C1 which is perpendicular to the surface of the support substrate 11 and which passes through the center of the surface of the support substrate 11 coincides with a center line C2 which is perpendicular to the surface of the intermediate structure body 20. Note that the intermediate structure body 20 and the support substrate 11 may be placed upside down. In this case, the support substrate 11 is fixed to the upper-side unit configured to fix and heat 43.

The support substrate 11 and the intermediate structure body 20 with the strip layer 13 interposed in between are heated respectively by the lower-side unit configured to fix and heat 33 and by the upper-side unit configured to fix and heat 43, and thereby the strip layer 13 is softened (step S13). The heating temperature is 250° C., for example. Note that the softening of the strip layer 13 was observed at 200° C. and at 220° C., as well. Accordingly, a heating temperature ranging from 200° C. to 250° C. can be set.

FIG. 4A shows a state before the movement to separate the support substrate 11 and the intermediate structure body 20 from each other is started. To put it differently, in the state, the center line C1 of the support substrate 11 coincides with the center line C2 of the intermediate structure body 20. FIG. 4B, on the other hand, shows the relative positions of the support substrate 11 and the intermediate structure body 20 at the time when the movement to separate the support substrate 11 and the intermediate structure body 20 from each other is finished. Both the lower-side unit configured to fix and heat 33 and the upper-side unit configured to fix and heat 43 are in a heated state, and thus strip layers 13a, 13b each have a low viscosity.

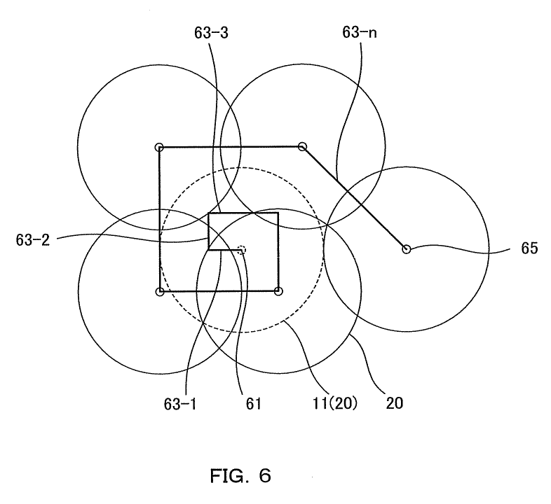

Subsequently, the procedure to move the support substrate 11 and the intermediate structure body 20 from their respective positions shown in FIG. 4A to their respective positions shown in FIG. 4B will be described. As FIGS. 1, 5, and 6 show, while each of the support substrate 11 and the intermediate structure body 20 is kept in the horizontal state, the upper-side unit configured to fix and heat 43 is moved with respect to the lower-side unit configured to fix and heat 33 so as to draw line segments (step S14). For example, the upper-side unit configured to fix and heat 43 is moved leftwards in FIG. 6 so as to draw a line segment. Then, the moving direction is turned by 90 degrees, and the upper-side unit configured to fix and heat 43 is moved so as to draw another line segment. In this way, the upper-side unit configured to fix and heat 43 is moved so as to draw plural line segments so that the distance between the center of the support substrate 11 and the center of the intermediate structure body 20 at the end point of each line segment can be longer than the corresponding distance at the start point of the line segment.

More detailed description will be given with reference to FIG. 6. In FIG. 6, the support substrate 11 is represented by a dashed line whereas the intermediate structure body 20 after the start of the movement is represented by solid lines. When the position of the support substrate 11 coincides with the position of the intermediate structure body 20, the position of the centerline C1 coincides with the position of the center line C2 (see FIG. 4A). The position of the centerlines C1 and C2 at this time will be referred to as a start point 61. The temperature of the central heating portions 35a, 45a and that of the peripheral heating portions 35b, 45b (see FIGS. 5A and 5B) are adjusted so that the strip layer 13 located between the support substrate 11 and the intermediate structure body 20 can have a uniform in-plane temperature distribution.

Once the strip layer 13 has become less viscous, the intermediate structure body 20 is moved with respect to the support substrate 11 leftwards in FIG. 6 at a constant speed, at 1 mm/s for example, and linearly by 30 μm along a line segment 63-1. The line segment 63-1 connects the start position to the end position (the start point, to the end point) of the center of the intermediate structure body 20 (corresponding to the position of the center line C2) in the movement. Then, the intermediate structure body 20 is moved from the end point of the line segment 63-1 upwards in FIG. 6 (substantially at 90 degrees with respect to the line segment 63-1) and linearly along a line segment 63-2 at a similar speed to that of the movement along the line-segment 63-1 by 35 μm, for example. Then, the intermediate structure body 20 is moved from the end point of the line segment 63-2 rightwards in FIG. 6 (substantially at 90 degrees with respect to the line segment 63-2) and linearly along a line segment 63-3 at a similar speed to that of the movement along the line-segment 63-1 by 65 μm, for example. From then on, the intermediate structure body 20 is moved in a similar manner so that the distance between the end point of each line segment and the adjacent line segment on the start point side may be either constant or gradually increasing, and, at the same time, the distance between the end point of each line segment and the center of the support substrate 11 may be longer than the distance between the start point of the line segment and the center of the support substrate 11, for example. The intermediate structure body 20 is repetitively moved until the center of the intermediate structure body 20 reaches a separation point 65, that is, until the outermost circumference of the support substrate 11 comes substantially in contact with the outermost circumference of the intermediate structure body 20 (step S15). After that, the upper-side table 41 to which the intermediate structure body 20 is drawn and fixed is moved upwards along the support columns 103, for example, and is then placed at a position such that neither the upper-side table 41 nor the intermediate structure body 20 can interfere with the lower-side table 31.

To put it differently, the plural line segments thus drawn include a first line segment 63-1 drawn in a first direction (e.g., leftwards in FIG. 6) and having a first length (e.g., 30 μm) as well as a second line segment 63-2 drawn in a second direction that intersects with the first direction (e.g., upwards in FIG. 6) and having a second length that is longer than the first length (e.g., 35 μm). In this manner, every time a new round of movement is carried out, the length of the line segment of the movement becomes longer than that for the previous round.

Subsequent processes will be described with reference to FIG. 1 and FIGS. 2B to 2E. The intermediate structure body 20 is removed from the upper-side unit configured to fix and heat 43. Then, the strip layer 13b is removed from the surface of the printed circuit board 21 of the intermediate structure body 20. Then, the intermediate structure body 20 is divided into individual pieces by dicing, for example. After that, the semiconductor chips 72 are fixed to and are electrically connected to the opposite surface of the printed circuit board 21 to the semiconductor chips 23 via the solder bumps 73. Then, the mother board 71 having the wirings is fixed to the resultant intermediate structure body 20 on the molding resin 27 side. The printed circuit board 21 is electrically connected to the mother board 71 through the metal fine wires 75. Then, the molding resin 77 is provided to mold the resultant intermediate structure body 20 together with the semiconductor chips 72. The resultant molding resin 77 and mother board 71 are divided into individual pieces by dicing, for example (step S16). After that, the solder bumps 79 are provided on the opposite surface of the mother board 71 to the molding resin 77. Thus the fabrication of the semiconductor device 1 is completed. Note that the semiconductor chips 72 may be fixed to and electrically connected to the opposite surface of the printed circuit board 21 to the semiconductor chip 23 via the semiconductor bumps 73 before the intermediate structural body 20 is divided into individual pieces. Then, the resultant intermediate structure body 20 together with the semiconductor chips 72 may be divided into individual pieces.

As has been described above, through the processes from step S11 to step S15 to manufacture the dual-sided semiconductor device 1, the wafer-like intermediate structure body 20 including the printed circuit board 21, the semiconductor chips 23, and the molding resin 27 can be separated from the support substrate 11 while the strip layer 13 formed between the intermediate structure body 20 and the support substrate 11 reduce the damage to be given to the printed circuit board 21 for the following reason. Specifically, the intermediate structure body 20 is moved with respect to the support substrate 11 in four different directions (i.e., in up-and-down directions and in right-and-left directions in a top plan view) so as to generate shear forces in the four different directions. Such shear forces weaken the bonding of the polymers of the strip layer 13 so as to make the separation easier. Consequently, the damage to the printed circuit board 21, such as cracks, rupture of wires, warpage of the printed circuit board 21, can be reduced.

In addition, the heating portions respectively provided in the lower-side unit configured to fix and heat 33 and in the upper-side unit configured to fix and heat 43 are divided along the circumferential direction into the central heating portions 35a, 45a and the peripheral heating portions 35b, 45b. Accordingly, the strip layer 13 can keep a substantially uniform low viscosity distribution within a plane. Consequently, the generation of a stress that would otherwise be caused by the difference in the viscosity can be avoided, and thus the damage to be given to the printed circuit board 21 can be reduced.

Then, when the process of step S16 is finished, the fabrication of the semiconductor device 1 with reduced damage to the printed circuit board 21 is completed. The lowering of the fabrication yield by the separation of the printed circuit board 21 from the support substrate 11 can be reduced in the above-described way, so that the lowering of the total fabrication yield of the dual-sided semiconductor device 1 can be reduced.

In addition, the apparatus for manufacturing the semiconductor device 1 has specifications that are suitable for the fabrication using a silicon wafer. Accordingly, if a silicon wafer is used as the support substrate 11 for the dual-sided semiconductor device 1, most portions of an existing manufacturing apparatus, except the above-described movement mechanism unit, can be used without special adjustment or jigs. Consequently, the increase in the manufacturing cost of the dual-sided semiconductor device 1 can be reduced.

### Second Embodiment

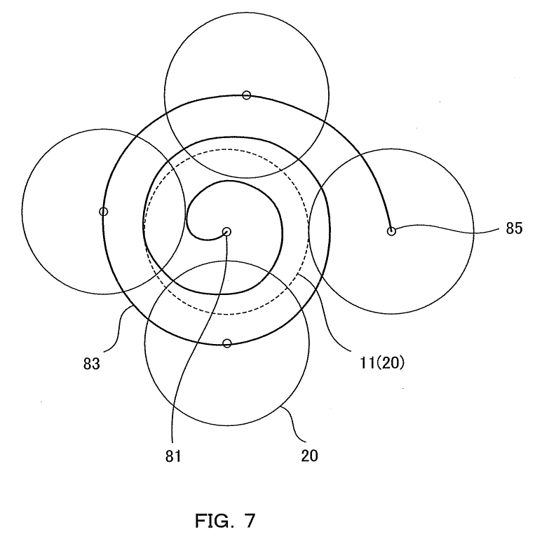

A method and an apparatus for manufacturing a semiconductor device according to a second embodiment will be described with reference to FIG. 7. The semiconductor device manufacturing method of the second embodiment differs from that of the first embodiment in the relative movement direction of the support substrate and the intermediate structure body. Note that if a portion in the second embodiment is the same as one in the first embodiment, the portion is denoted by the same reference numeral as used in the first embodiment, and the detailed description of the portion will not be given.

The semiconductor device of the second embodiment is similar to the semiconductor device 1 of the first embodiment, and the apparatus for manufacturing the semiconductor device 1 of the second embodiment is similar to that of the first embodiment. The processes from step S11 to step S13 and the processes from step S15 of the method for manufacturing the semiconductor device 1 of the second embodiment are the same as those of the first embodiment. To be more specific, the process of step S14 of the first embodiment is replaced by the following process. As FIG. 7 shows, the upper-side unit configured to fix and heat 43 is moved with respect to the lower-side unit configured to fix and heat 33 so that the distance between the center of the intermediate structure body 20 and the center of the support substrate 11 can be gradually increased with a spirally curved line 83 being drawn by the center of the intermediate structure body 20 (step S21). The curved line 83 starts from a starting point 81 to a separation point 85.

At step S21, the intermediate structure body 20 is moved with respect to the support substrate 11 in the in-plane directions that are always changing. Accordingly, shear forces in all the directions are generated. Such shear forces weaken the bonding of the polymers of the strip layer 13 so as to make the separation easier. In addition, the second embodiment has similar effects to those obtained by the first embodiment.

### Third Embodiment

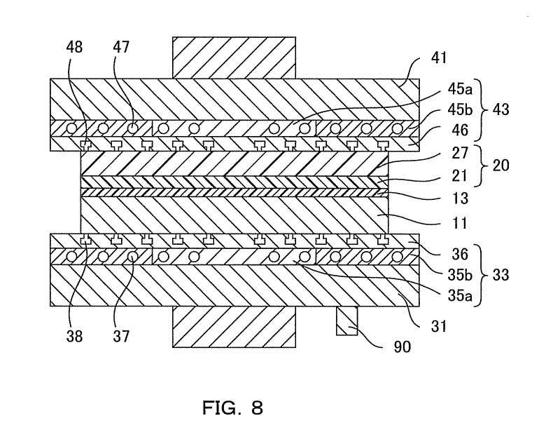

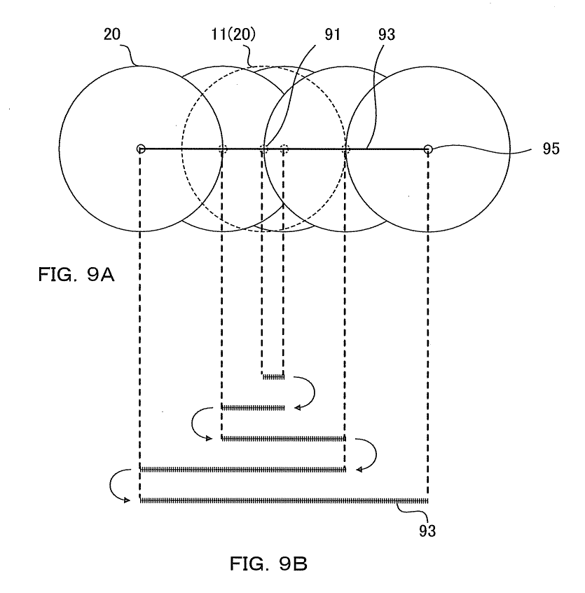

A method and an apparatus for manufacturing a semiconductor device according to a third embodiment will be described with reference to FIG. 8 and FIGS. 9A and 9B. The semiconductor-device manufacturing method of the third embodiment differs from that of the first embodiment in the fact that an ultrasonic power is applied and in the relative movement direction of the support substrate and the intermediate structure body. If a portion in the third embodiment is the same as one in the first and second embodiments, the portion is denoted by the same reference numeral as used in the first and second embodiments, and the detailed description of the portion will not be given.

The semiconductor device of the third embodiment is similar to the semiconductor device 1 of the first embodiment. The apparatus for manufacturing the semiconductor device 1 of the third embodiment is similar to that of the first embodiment except that an ultrasonic-power connecting portion 90 to supply an ultrasonic power generated by an unillustrated ultrasonic-power generating mechanism unit is added to the lower-side table 31 of the manufacturing apparatus of the first embodiment. Note that the ultrasonic-power connecting portion 90 may be added not to the lower-side table 31 but to the upper-side table 41.

The processes of step S11 and step S12 and the processes from step S15 of the method for manufacturing the semiconductor device 1 of the third embodiment are the same as those of the first embodiment. To be more specific, after the strip layer 13 is softened as in the case of step S13 of the first embodiment, ultrasonic vibrations (e.g., with a frequency of approximately 20 kHz and an amplitude of approximately 1.5 μm) is applied to the lower-side table 31 via the ultrasonic-power connecting portion 90 (step S31).

Then, the process of step S14 of the first embodiment is replaced by the following process. As FIG. 9A shows, while each of the support substrate 11 and the intermediate structure body is kept in the horizontal state, the upper-side unit configured to fix and heat 43 is moved with respect to the lower-side unit configured to fix and heat 33 so as to draw line segments (step S32). For example, the upper-side unit configured to fix and heat 43 is moved rightwards in FIG. 9A so as to draw a line segment. Then, the moving direction is turned by 180 degrees, and the upper-side unit configured to fix and heat 43 is moved so as to draw a new line segment. Here, a portion of the new line segment overlaps the previous line segment. In this way, the upper-side unit configured to fix and heat 43 is repetitively moved so as to draw plural line segments so that the distance between the center of the support substrate 11 and the center of the intermediate structure body 20 at the end point of each line segment can be longer than the corresponding distance at the start point of the line segment. FIG. 9B shows line segments 93 thus drawn which are shifted from one another in up-and-down direction so that the length of each line segment 93 can be more recognizable. As FIGS. 9A and 9B shows, as the center of the intermediate structure body 20 moves from a start point 91 to a separation point 95, the line segment 93 gradually becomes longer. The width of each line segment 93 means an ultrasonic power applied during the movement. The direction of the ultrasonic power may be either the same as or different from the direction in which the intermediate structure body 20 is moved with respect to the support substrate 11.

To put it differently, the plural line segments thus drawn include a first line segment 93 drawn in a first direction (e.g., rightwards in FIG. 9B) and having a first length as well as a second line segment 93 drawn in a second direction that is opposite to the first direction (i.e., that differs from the first direction by 180 degrees) and having a second length that is longer than the first length. In this manner, every time a new round of movement is carried out, the length of the line segment of the movement becomes longer than that for the previous round.

The intermediate structure body 20 is moved with respect to the support substrate 11 in two different directions (i.e., rightwards and leftwards in a top plan view) at steps S31 and S32 so as to generate shear forces in the two different directions. In addition, shear forces in two predetermined directions are generated by the ultrasonic power. Such shear forces weaken the bonding of the polymers of the strip layer 13 so as to make the separation easier. In addition, the third embodiment has similar effects to those obtained by the first embodiment.

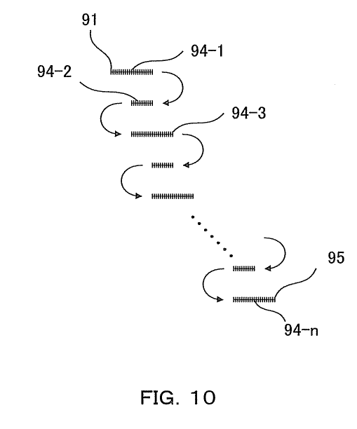

FIG. 10 shows a modification of the third embodiment. FIG. 10 is a diagram corresponding to FIG. 9B, but the lengths of the line segments of the modification differ from those of the third embodiment. The process of step S14 of the first embodiment is replaced by the following process. While each of the support substrate 11 and the intermediate structure body is kept in the horizontal state, the upper-side unit configured to fix and heat 43 is moved with respect to the lower-side unit configured to fix and heat 33 so as to draw line segments (step S33). As FIG. 10 shows, the upper-side unit configured to fix and heat 43 is moved rightwards, for example, in FIG. 10 so as to draw a line segment 94-1. Then, the moving direction is turned by 180 degrees, and the upper-side unit configured to fix and heat 43 is moved leftwards in FIG. 10 so as to draw a new line segment 94-2 having half the length of the line segment 94-1 and overlapping a portion of the line segment 94-1. Then, the upper-side unit configured to fix and heat 43 is moved in the same direction as in the case of the line segment 94-1 so as to draw a new line segment 94-3 having the same length as that of the line segment 94-1. Thus the movement of the upper-side unit configured to fix and heat 43 is repeated. The position of the end point for a line segment 94-n drawn by the rightward movement moves gradually farther away from the starting point 91 and eventually reaches the separation point 95.

To put it differently, the plural line segments thus drawn include a first line segment 94-1 drawn in a first direction (e.g., rightwards in FIG. 10) and having a first length as well as a second line segment 94-2 drawn in a second direction that is opposite to the first direction (e.g., leftwards in FIG. 10) and having a second length that is shorter than the first length (approximately a half length of the first length). Each of the first and second line segments has the same length throughout repetitive movements.

The movements at step S33 allows the modification of the third embodiment to have similar effects to those obtained by the third embodiment. In addition, the modification of the third embodiment needs a smaller space for the operation than the space needed in the third embodiment.

Incidentally, the separation of the support substrate 11 and the intermediate structure body 20 from each other with the application of an ultrasonic power may be carried out by the moving method of the first or second embodiment.

### Fourth Embodiment

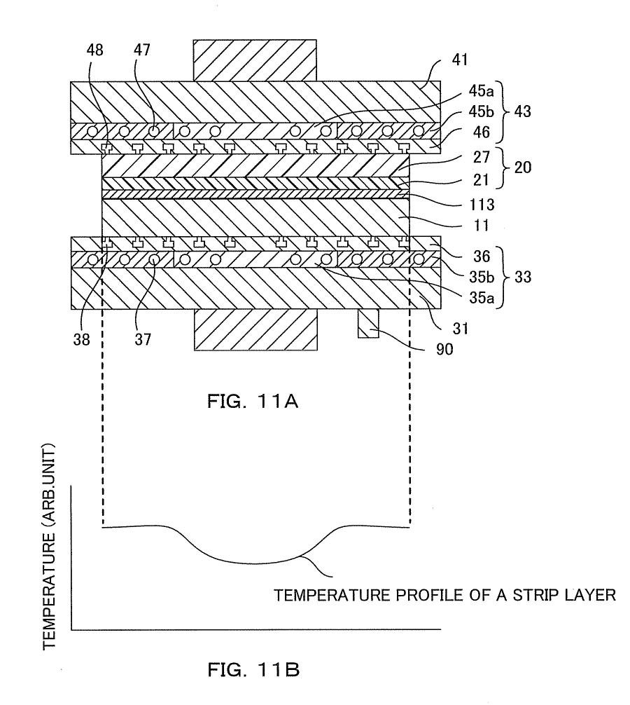

A method and an apparatus for manufacturing a semiconductor device according to a fourth embodiment will be described with reference to FIGS. 11A and 11B. The semiconductor-device manufacturing method of the fourth embodiment differs from that of the third embodiment in the fact that the strip layer formed as the interface between the support substrate and the intermediate structure body is made of metal. If a portion in the fourth embodiment is the same as one in the first and third embodiments, the portion is denoted by the same reference numeral, and the detailed description of the portion will not be given.

The semiconductor device of the fourth embodiment is similar to the semiconductor device 1 of the first embodiment. In addition, as FIG. 11A shows, the apparatus for manufacturing the semiconductor device 1 of the fourth embodiment is similar to that of the third embodiment. In addition, as FIG. 11A shows (see also FIG. 2A), a strip layer 113 made of metal is formed as the interface between the wafer-like support substrate 11 and the intermediate structure body 20 before the separation. The strip layer 113 has a two-layer structure, for example, obtained by including a layer of Ti having a thickness of approximately 0.1 μm and a layer of Ni which is formed by the sputtering method to have a thickness of approximately 0.1 μm and which is placed on top of the Ti-layer. Note that the strip layer 113 may be made of some other metals that are not so highly adhesive.

The processes of step S11 and step S12 and the processes from step S16 of the method for manufacturing the semiconductor device 1 of the fourth embodiment are the same as those of the first and third embodiments. To be more specific, the process of step S13 of the first embodiment is replaced by the following process. The heating temperature of the central heating portions 35a, 45a is set at a relatively low temperature, which is 150° C., for example. On the other hand, the heating temperature of the peripheral heating portions 35b and 45b is set at a relatively high temperature, which is 250° C., for example. In addition, similar ultrasonic vibrations to those applied at step S31 of the third embodiment are applied (step S41).

Then, the process of step S14 of the first embodiment is replaced by the following process. While each of the support substrate 11 and the intermediate structure body 20 is kept in the horizontal state, the upper-side unit configured to fix and heat 43 is moved horizontally back and forth with respect to the lower-side unit configured to fix and heat 33 at a constant speed (oscillating motion). Either concurrently with or following the oscillating motion, the upper-side unit configured to fix and heat 43 is moved with respect to the lower-side unit configured to fix and heat 33 upwards, i.e., in directions perpendicular to the plane such that the two units 43, 33 can be pulled away from each other and brought back closely to each other (step S42). The amount of the upward movement is approximately equal to or smaller than one tenth of the amount of the horizontal movement.

Then, the process of step S15 of the first embodiment is replaced by the following process. The horizontal sliding movements in two directions and up-and-down movements are repetitively carried out until the support substrate 11 is separated from the intermediate structure body 20 at the strip layer 113 (step S43). Incidentally, the resin of the strip layer 13 having a certain viscosity must be cut in the first to third embodiments. In contrast, since each of the strip layer 113 and the support substrate 11 located opposed to the strip layer 113 is in the solid phase at a temperature equal to or lower than 300° C. in the fourth embodiment, the horizontal sliding movements in the fourth embodiment have only to separate the atoms of the strip layer 113 by a much smaller amount than in the case of the strip layer 13. Accordingly, in contrast to the case of the first to third embodiments, it is not necessary, in the fourth embodiment, to move the upper-side unit configured to fix and heat 43 until the peripheral area of the support substrate 11 is separated from the peripheral are of the intermediate structure portion 20. In the fourth embodiment, the upper-side unit configured to fix and heat 43 has only to be moved so that the center of the intermediate structure body 20 can be moved with respect to the center of the support substrate 11 within a certain area. The movement of the center of the intermediate structure body may be either cyclical or not cyclical.

In the fourth embodiment, the strip layer 113 is made of metal. In addition, while the ultrasonic vibration is being applied, the upper-side unit configured to fix and heat 43 is moved with respective to the lower-side unit configured to fix and heat 33 within a certain area through the processes from step S41 to step S43. Thus, plural shear forces of different directions can be generated between the intermediate structure body 20 and the support substrate 11, so that the intermediate structure body 20 together with the strip layer 113 is separated from the support substrate 11. Since the central portion is heated to a relatively low temperature and the peripheral portion is heated to a relatively high temperature, the difference in thermal expansion between the strip layer 113 and the support substrate 11 varies between these portions. The variation in the thermal-expansion difference triggers the separation. Note that the temperature distribution may be such that the central portion may be set at a relatively high temperature and the peripheral portion may be set at a relatively low temperature. In addition, if the strip layer 113 has a larger stress or on the like conditions, the temperature distribution may be such that the central portion and the peripheral portion may have approximately the same temperature. Note also that the strip layer 113 still attached to the intermediate structure body 20 after the separation is removed from the intermediate structure body 20 by etching.

The strip layer 113 made of metal and formed between the intermediate structure body 20 and the support substrate 11 allows the intermediate structure body 20 and the support substrate 11 to be separated from each other without damaging the printed circuit board 21. In addition, as in the case of the first embodiment, the fabrication of the semiconductor device 1 with reduced damage to the printed circuit board 21 is completed through the process of step S16 and the lowering of the total fabrication yield of the dual-sided semiconductor device 1 is suppressed.

The invention is not limited to the above-described embodiments. Various modifications may be made without departing from the scope of the invention.

For example, according to the methods of the above-described embodiments, the support substrate on the lower side is fixed whereas the intermediate structure body on the upper side is moved. However, other mechanisms may be employed as long as the relative positions of the support substrate and of the intermediate structure body are maintained. So, in a possible mechanism, the middle point of the center of the support substrate and the center of the intermediate structural body may be located substantially at a fixed position. In this case, a smaller work space is needed for separation of the intermediate structure body from the support substrate.

In addition, the support substrate of each of the above-described embodiments is a silicon wafer. Alternatively, the support substrate may be a wafer made of other semiconductor materials, metal, glass, ceramics, or resin. Still alternatively, the support substrate may be a wafer with semiconductor materials, metal, glass, ceramics, or resin being formed on the surface of the support substrate.

In addition, in the first to third embodiments, the upper-side unit configured to fix and heat is moved horizontally with respect to the lower-side unit configured to fix and heat at a constant speed. Either concurrently with or following the horizontal movement, the upper-side unit configured to fix and heat may be moved with respect to the lower-side unit configured to fix and heat upwards, i.e., in a direction perpendicular to the plane such that the two units can be pulled away from each other.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A method of manufacturing a semiconductor device, comprising:
forming a resin layer on a wafer-like support substrate, the resin being a thermoplastic resin;
forming a wafer-like intermediate structure body on the resin layer, the intermediate structure body including a printed circuit board, a semiconductor chip mounted on the printed circuit board and a molding resin to cover a upper surface of the printed circuit board and the semiconductor chip;
fixing the support substrate to a first unit, the first unit being configured to fix and heat the support substrate;
fixing the intermediate structure body to a second unit arranged opposite to the first unit, the second unit being configured to fix and heat the intermediate structure body;
heating the support substrate and the intermediate structure body by the first unit or the second unit, so as to soften the resin layer; and
moving the second unit with respect to the first unit along each of a plurality of line segments or a curve, so as to enlarge a distance between a center of the support substrate and a center of the intermediate structure body as the second unit moves, while the support substrate and the intermediate structure body being kept in the horizontal state, and until the support substrate and the intermediate structure body are separated.

2. The method of manufacturing a semiconductor device according to claim 1, wherein the plurality of line segments include a first line segment drawn in a first direction and having a first length as well as a second line segment drawn in a second direction that intersects with the first direction and having a second length that is longer than the first length.

3. The method of manufacturing a semiconductor device according to claim 1, wherein the curve is a spiral curve.

4. The method of manufacturing a semiconductor device according to claim 1, wherein the plurality of line segments include a first line segment drawn in a first direction and having a first length as well as a second line segment drawn in a second direction that is opposite to the first direction and having a second length that is longer than the first length.

5. The method of manufacturing a semiconductor device according to claim 1, wherein the plurality of line segments include a first line segment drawn in a first direction and having a first length as well as a second line segment drawn in a second direction that is opposite to the first direction and having a second length that is shorter than the first length.

6. The method of manufacturing a semiconductor device according to claim 1, wherein an ultrasonic power is supplied to the resin layer through the support substrate or the intermediate structure body, when the second unit is moved with respect to the first unit.

7. The method of manufacturing a semiconductor device according to claim 1, wherein the support substrate is a wafer made of semiconductor material, metal, glass, ceramics or resin.

8. The method of manufacturing a semiconductor device according to claim 1, wherein the support substrate is a wafer with semiconductor material, metal, glass, ceramics or resin being formed on a surface of the support substrate.

9. The method of manufacturing a semiconductor device according to claim 1, wherein the first unit and the second unit have a drawing and fixing mechanism unit, the drawing and fixing mechanism unit being configured to draw and fix the support substrate or intermediate structure body.

10. The method of manufacturing a semiconductor device according to claim 1, wherein at least one of either the first unit or the second unit is capable of heating a central portion and a peripheral portion of the support substrate and the intermediate structure body separately.

11. A method of manufacturing a semiconductor device, comprising:
forming a metal layer on a wafer-like support substrate;
forming a wafer-like intermediate structure body on the metal layer, the intermediate structure body including a printed circuit board, a semiconductor chip mounted on the printed circuit board and a molding resin to cover an upper surface of the printed circuit board and the semiconductor chip;
fixing the support substrate to a first unit, the first unit being configured to fix and heat the support substrate;
fixing the intermediate structure body to a second unit arranged opposite to the first unit, the second unit being configured to fix and heat the intermediate structure body;
heating the support substrate and the intermediate structure body by the first unit or the second unit;
supplying a ultrasonic power to the metal layer through the support substrate or the intermediate structure body;
moving the second unit with respect to the first unit in a horizontal direction and at a constant speed with vibration, while the support substrate and the intermediate structure body being kept in the horizontal state; and
moving the second unit with respect to the first unit in a vertical direction and at a constant speed with vibration, wherein the horizontal movement and the vertical movement are repeated until the support substrate and the intermediate structure body are separated.

12. The method of manufacturing a semiconductor device according to claim 11, wherein the support substrate is a wafer made of semiconductor material, metal, glass, ceramics or resin.

13. The method of manufacturing a semiconductor device according to claim 11, wherein the support substrate is a wafer with semiconductor material, metal, glass, ceramics or resin being formed on a surface of the support substrate.

14. The method of manufacturing a semiconductor device according to claim 11, wherein the first unit and the second unit have a drawing and fixing mechanism unit, the drawing and fixing mechanism unit being configured to draw and fix the support substrate or intermediate structure body.

15. The method of manufacturing a semiconductor device according to claim 11, wherein at least one of either the first unit or the second unit is capable of heating a central portion and a peripheral portion of the support substrate and the intermediate structure body separately.

16. An apparatus for manufacturing a semiconductor device, comprising:
a first unit to fix and heat including a first heating portion and a second heating portion respectively to heat a center portion of a work and a peripheral portion of the work independently, the first heating portion and the second heating portion having a vacuum chuck on the side of the work;
a second unit to fix and heat including a third heating portion and a forth heating portion respectively to heat the center portion of the work and the peripheral portion of the work independently, the third heating portion and the forth heating portion having a vacuum chuck on the side of the work, the second unit being arranged oppositely to the first unit; and
a movement mechanism unit configured to move the second unit with respect to the first unit in a plurality of mutually different directions on a plane when the work is heated.

17. The apparatus for manufacturing a semiconductor device according to claim 16, wherein at least one of either the first unit or the second unit is connected to a unit to generate ultrasonic power.

18. The apparatus for manufacturing a semiconductor device according to claim 16, wherein the work consists of a wafer-like support substrate, a connection layer formed on the support substrate and a wafer-like intermediate structure body, the intermediate structure body including a printed circuit board, a first semiconductor chip mounted on the printed circuit board and a first molding resin to cover an upper surface of the printed circuit board and the first semiconductor chip.
